(19) United States
(12) Patent Application Publication
(10) Pub. No.: US 2026/0209936 A1
(43) Pub. Date: Jul. 23, 2026

(54) METHOD OF PROCESSING SUBSTRATE, METHOD OF MANUFACTURING SEMICONDUCTOR DEVICE, SUBSTRATE PROCESSING APPARATUS, AND RECORDING MEDIUM

(71) Applicant: KOKUSAI ELECTRIC CORPORATION, Tokyo (JP)

(72) Inventors: Shota TANAKA, Toyama-shi (JP); Yuya MIYANISHI, Toyama-shi (JP); Hiroki HATTA, Toyama-shi (JP)

(73) Assignee: KOKUSAI ELECTRIC CORPORATION, Tokyo (JP)

(21) Appl. No.: 19/567,300

(22) Filed: Mar. 16, 2026

Related U.S. Application Data
(63) Continuation of application No. PCT/JP2023/036541, filed on Oct. 6, 2023.

(51) Int. Cl. C23C 16/455; C23C 16/44; C23C 16/448

(52) U.S. Cl. CPC C23C 16/45523; C23C 16/4412; C23C 16/448

(57) ABSTRACT

A technique includes: a first step including: (a1) storing a process gas in a reservoir; and a second step of performing a cycle a predetermined number of times after the first step, the cycle including sequentially performing: (b1) storing the process gas in the reservoir; and (b2) supplying at least a portion of the process gas in the reservoir to a substrate accommodated in a process chamber.

### CROSS-REFERENCE TO RELATED APPLICATION

This application is a Bypass Continuation Application of PCT International Application No. PCT/JP2023/036541, filed on Oct. 6, 2023, the disclosure of which is incorporated herein in its entirety by reference.

### TECHNICAL FIELD

The present disclosure relates to a method of processing a substrate, a method of manufacturing a semiconductor device, a substrate processing apparatus, and a program.

### BACKGROUND

A process of processing a substrate may include performing, a predetermined number of times, a step of storing a process gas in a reservoir and a step of supplying the process gas stored in the reservoir to the substrate. The present disclosure provides a technique capable of suppressing variations in substrate processing.

### SUMMARY

According to embodiments of the present disclosure, there is provided a technique including: a first step including: (a1) storing a process gas in a reservoir; and a second step of performing a cycle a predetermined number of times after the first step, the cycle including sequentially performing: (b1) storing the process gas in the reservoir; and (b2) supplying at least a portion of the process gas in the reservoir to a substrate accommodated in a process chamber.

### BRIEF DESCRIPTION OF DRAWINGS

The accompanying drawings, which are incorporated in and constitute a part of the specification, illustrate embodiments of the present disclosure.

FIG. 1 is a longitudinal cross-sectional view schematically illustrating a substrate processing apparatus according to embodiments of the present disclosure.

FIG. 2A is a diagram illustrating a first process gas supply system according to embodiments of the present disclosure.

FIG. 2B is a diagram illustrating a second process gas supply system according to embodiments of the present disclosure.

FIG. 2C is a diagram illustrating an exhaust system according to embodiments of the present disclosure.

FIG. 3 is a schematic configuration diagram of a controller of the substrate processing apparatus according to embodiments of the present disclosure and illustrates a control system of the controller in a block diagram.

FIGS. 4A to 4H are diagrams schematically illustrating changes in an amount of a first process gas in a tank according to embodiments of the present disclosure.

FIGS. 5A to 5G are diagrams schematically illustrating an amount of a first process gas in a tank in a comparative example.

FIG. 6A is a flowchart of a substrate processing process according to embodiments of the present disclosure.

FIG. 6B is a flowchart of a preparation step according to embodiments of the present disclosure.

FIG. 6C is a flowchart of a film processing step according to embodiments of the present disclosure.

FIG. 6D is a flowchart of a first process gas supply step according to embodiments of the present disclosure.

FIG. 7 is a flowchart of a preparation step according to Modification 1 of the present disclosure.

FIG. 8 is a flowchart of a preparation step according to Modification 2 of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

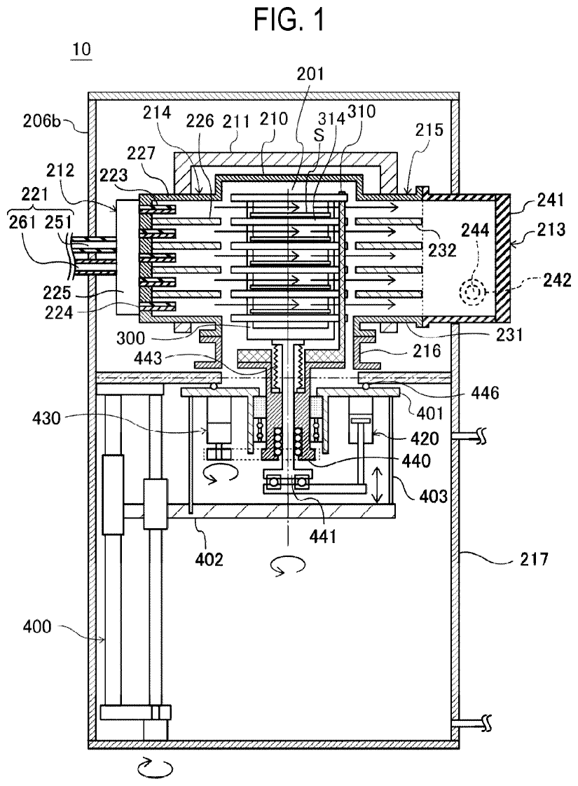

Embodiments of the present disclosure will now be described mainly with reference to FIGS. 1 to 8. The drawings used in the following description are all schematic, and dimensional relationships, ratios, and the like of various elements shown in the drawings do not always match the actual ones. Further, the dimensional relationships, ratios, and the like of various elements between plural figures do not always match each other.

### (1) Configuration of Substrate Processing Apparatus

A configuration of a substrate processing apparatus 10 will be described with reference to FIG. 1.

The substrate processing apparatus 10 includes a reaction tube storage chamber 206b. A reaction tube 210, a heater 211 as a heating part (furnace body) installed around an outer periphery of the reaction tube 210, a gas supply structure 212 as a gas supply part, and a gas exhaust structure 213 as a gas exhaust part are provided inside the reaction tube storage chamber 206b. The gas supply part may include an upstream side rectifier 214 and nozzles 223 and 224, which will be described later. The gas exhaust part may include a downstream side rectifier 215, which will be described later. A section of the reaction tube 210 in which a substrate S is processed is referred to as a process chamber 201. The process chamber 201 may also be referred to as a processing space in which the substrate S is accommodated.

A gas supplied into the reaction tube 210 from the gas supply structure 212 moves in a horizontal direction relative to the substrate S and is exhausted from the gas exhaust structure 213. The upstream side rectifier 214 is provided between the reaction tube 210 and the gas supply structure 212. The downstream side rectifier 215 is provided between the reaction tube 210 and the gas exhaust structure 213. The lower end of the reaction tube 210 is supported by a manifold 216. Heat generated by the heater 211 heats the substrate S and a gas within the process chamber 201.

The gas supply structure 212 has a distributor 225 to which gas supply pipes 251 and 261 are connected and which distributes a gas supplied from the respective gas supply pipes. A plurality of nozzles 223 and 224 are provided on the downstream side of the distributor 225. In the present embodiment, the gas supply pipes 251 and 261 are also collectively referred to as a gas supply pipe 221. Each nozzle may also be referred to as a gas discharge part. The distributor 225 is configured such that a gas is supplied from the gas supply pipe 251 to the nozzle 223 and a gas is supplied from the gas supply pipe 261 to the nozzle 224. The upstream side rectifier 214 includes a housing 227 and partition plates 226. The nozzles 223 and 224 are provided between the partition plates 226 and between the partition plates 226 and the housing 227. The downstream side rectifier 215 includes a housing 231 and partition plates 232. The gas exhaust structure 213 mainly includes a housing 241, an exhaust pipe connector 242, and an exhaust hole 244.

A transfer chamber 217 is formed below the reaction tube 210. Transfer of the substrate S between the inside and outside of the transfer chamber 217 through a substrate loading port (not shown) by a transfer robot (not shown) and loading/unloading of the substrate S to and from a substrate support 300 (hereinafter sometimes simply referred to as a boat) in the transfer chamber 217 are performed inside the transfer chamber 217.

A vertical driving mechanism 400 moves the substrate support 300 and a partition plate support 310 up and down between the inside of the reaction tube 210 and the inside of the transfer chamber 217. FIG. 1 shows a state in which the substrate support 300 and the partition plate support 310 are raised by the vertical driving mechanism 400 and stored inside the reaction tube 210. The vertical driving mechanism 400 includes a rotation driving mechanism 430 that rotates the substrate support 300 and the partition plate support 310 together, and a boat lifting mechanism 420 that drives the substrate support 300 in a vertical direction relative to the partition plate support 310. The rotation driving mechanism 430 and the boat lifting mechanism 420 are fixed to a base flange 401, serving as a lid, which is supported by side plates 403 on a base plate 402. An O-ring 446 for vacuum sealing is provided on the upper surface of the base flange 401. A support 440 fixed to the partition plate support 310 and a support 441 fixed to the substrate support 300 are connected by a vacuum bellows 443.

A plurality of substrates S are placed on the substrate support 300 at predetermined intervals in a vertical direction. A plurality of partition plates 314 are accommodated on the partition plate support 310 directly below the substrates S and on either or both of the upper and lower sides of the substrates S. In a substrate processing process to be described later, it is desirable that the heights of the partition plates 314 be aligned with the heights of the partition plates 226 and 232. As a result, a horizontal gas flow in which a vertical flow is suppressed from the partition plate 226, over the substrate S, to the partition plate 232 is easily formed, thereby enabling uniform processing of each substrate S.

FIG. 1 shows an example in which five substrates S are supported by the substrate support 300. However, the present disclosure is not limited thereto. For example, the substrate support 300 may be configured to support about 5 to 50 substrates S. In this specification, the notation of a numerical range such as “5 to 50” means that the lower and upper limit values are included in the range. Thus, for example, “5 to 50” means “5 or more and 50 or less.” The same applies to other numerical ranges.

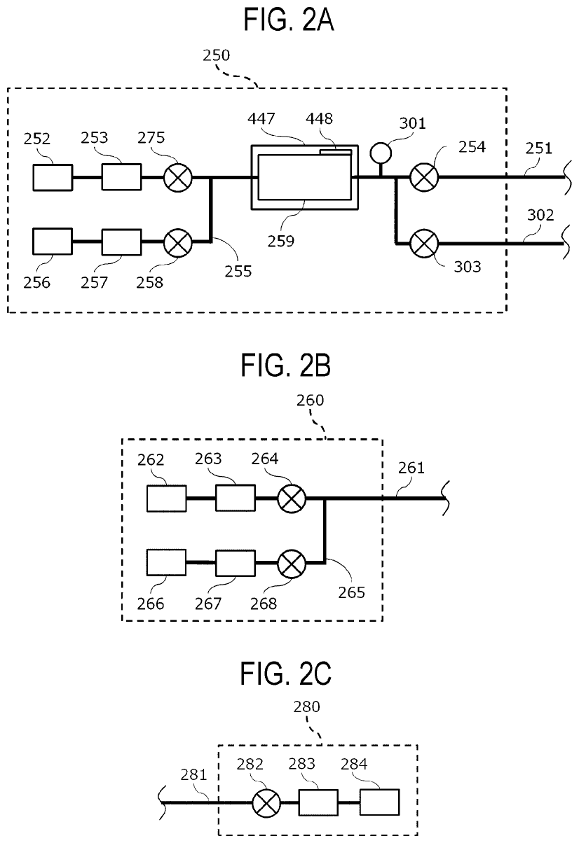

As shown in FIG. 2A, the gas supply pipe 251 is provided, in order from an upstream side, with a first process gas source 252, a mass flow controller (MFC) 253 as a flow rate controller, a valve 275 as an opening/closing valve, a tank 259 as a reservoir for storing a gas therein, a sensor 301 as a pressure measuring device (pressure measuring part) for measuring the internal pressure of the tank 259, and a valve 254.

The tank 259 is provided with a sensor 448 as a temperature measuring device (temperature measuring part) for measuring the temperature of the tank 259 and/or a gas stored in the tank 259. The tank 259 is also provided with a heater 447 as a temperature controller (temperature control part) for adjusting the temperature of the tank 259 and/or the gas stored in the tank 259. Here, a portion of the gas supply pipe 251 having a larger diameter than upstream and downstream portions, or a spiral pipe, may be used as a reservoir. By opening/closing the upstream side valve 275 and the downstream side valve 254 of the tank 259, the gas supplied from the gas supply pipe 251 can be temporarily stored (charged) in the tank 259, or the gas stored in the tank 259 can be supplied into the process chamber 201.

The first process gas source 252 is a gas source for supplying a first process gas (also referred to as a raw material gas) as a process gas. As the first process gas source 252, a vaporizer or the like that generates the first process gas by vaporizing a liquid or solid may be used. Hereinafter, a case in which a gas obtained by vaporizing a liquid or solid is used as the first process gas will be described as an example.

The gas supply pipe 251, the MFC 253, the valve 275, the tank 259, the sensor 301, and the valve 254 mainly constitute a first process gas supply system 250 (also referred to as a raw material gas supply system). The first process gas source 252 may be included in the first process gas supply system 250. The sensor 448 and the heater 447 may also be included in the first process gas supply system 250. Further, in addition to the heater 447, heaters (not shown) may be provided at respective portions in the first process gas supply system 250 to adjust the temperature of the first process gas supply system 250. The first process gas supply system 250 is an example of a process gas supply system that stores the first process gas as a process gas in the tank 259 and supplies the first process gas stored in the tank 259 to the substrate S.

In the gas supply pipe 251, a gas exhaust pipe 302 for discharging the gas in the tank 259 to the outside of the process chamber 201 without supplying it to the process chamber 201 is connected between the sensor 301 and the valve 254. A valve 303 is provided in the gas exhaust pipe 302. The gas exhaust pipe 302 and the valve 303 mainly constitute a first process gas exhaust system (also referred to as a raw material gas exhaust system). The first process gas exhaust system may be included in the first process gas supply system 250.

In the gas supply pipe 251, a gas supply pipe 255 is connected between the valve 275 and the tank 259. The gas supply pipe 255 is provided, in order from an upstream side, with an inert gas source 256, an MFC 257, and a valve 258. An inert gas is supplied from the inert gas source 256. The gas supply pipe 255, the MFC 257, and the valve 258 mainly constitute a first inert gas supply system. The inert gas source 256 may be included in the first inert gas supply system. The first inert gas supply system may be included in the first process gas supply system 250.

As shown in FIG. 2B, the gas supply pipe 261 is provided, in order from an upstream side, with a second process gas source 262, an MFC 263, and a valve 264. The second process gas source 262 is a gas source for supplying a second process gas (also referred to as a reaction gas) as a process gas. The gas supply pipe 261, the MFC 263, and the valve 264 mainly constitute a second process gas supply system 260 (also referred to as a reaction gas supply system). The second process gas source 262 may be included in the second process gas supply system 260.

In the gas supply pipe 261, a gas supply pipe 265 is connected to the downstream side of the valve 264. The gas supply pipe 265 is provided, in order from an upstream side, with an inert gas source 266, an MFC 267, and a valve 268. An inert gas is supplied from the inert gas source 266. The gas supply pipe 265, the MFC 267, and the valve 268 mainly constitute a second inert gas supply system. The inert gas source 266 may be included in the second inert gas supply system. The second inert gas supply system may be included in the second process gas supply system 260.

As shown in FIG. 2C, a vacuum pump 284 as a vacuum exhaust device is connected to an exhaust pipe 281 via a valve 282 and an APC (Auto Pressure Controller) valve 283 as a pressure regulator (pressure regulating part), such that the inside of the reaction tube 210 can be vacuum-exhausted so that the internal pressure of the reaction tube 210 becomes a predetermined pressure (degree of vacuum). The exhaust pipe 281 is connected to the exhaust pipe connector 242. The exhaust pipe 281, the valve 282, and the APC valve 283 are collectively referred to as an exhaust system 280. The exhaust system 280 is also referred to as a process chamber exhaust system. The vacuum pump 284 may be included in the exhaust system 280.

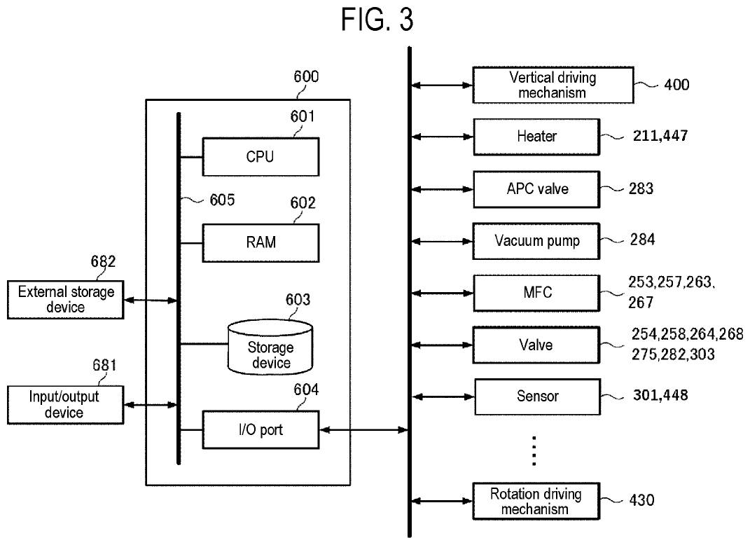

Next, a controller as a control part (control means) will be described with reference to FIG. 3. The substrate processing apparatus 10 includes a controller 600 that controls operations of respective parts of the substrate processing apparatus 10.

An outline of the controller 600 is shown in FIG. 3. The controller 600 is configured as a computer including a CPU (Central Processing Unit) 601, a RAM (Random Access Memory) 602, a storage device 603 as a storage part, and an I/O port 604. The RAM 602, the storage device 603, and the I/O port 604 are configured to exchange data with the CPU 601 via an internal bus 605.

The storage device 603 is composed of, for example, a flash memory, an HDD (Hard Disk Drive), or the like. A control program for controlling operations of the substrate processing apparatus 10, a process recipe in which the procedures and conditions for substrate processing are written, etc. are readably stored in the storage device 603.

The process recipe functions as a program that causes the controller 600 to execute each sequence in a substrate processing process, which will be described later, to obtain an expected result. Hereinafter, the process recipe and the control program may be generally and simply referred to as a “program.” When the term “program” is used herein, it may indicate a case of including the recipe only, a case of including the control program only, or a case of including both the recipe and the control program. The RAM 602 is configured as a memory area (work area) in which programs or data read by the CPU 601 are temporarily stored.

The I/O port 604 is connected to the above-described vertical driving mechanism 400, heaters 211 and 447, APC valve 283, vacuum pump 284, MFCs 253, 257, 263, and 267, valves 254, 258, 264, 268, 275, 282, and 303, sensors 301 and 448, rotation driving mechanism 430, and the like.

The CPU 601 is configured to read and execute the control program from the storage device 603, and to read the process recipe from the storage device 603 in response to, for example, an input of an operation command from the input/output device 681. Then, the CPU 601 is configured to control the vertical driving mechanism 400 to raise and lower the substrate support 300, the heater 211 to heat the substrate, the APC valve 283 to adjust the opening degree, the vacuum pump 284 to start and stop, the MFCs 253, 257, 263, and 267 to adjust the flow rates of various gases, the valves 254, 258, 264, 268, 275, 282, and 303 to open and close, the sensor 301 to measure the internal pressure of the tank 259, the sensor 448 to measure the temperature of the tank 259 and/or the gas stored in the tank 259, the heater 447 to control the temperature of the tank 259 and/or the gas stored in the tank 259, and the rotation driving mechanism 430 to rotate the substrate support 300 and adjust its rotation speed, and the like, in accordance with the contents of the read process recipe. The MFCs 253, 257, 263, and 267, the valves 254, 258, 264, 268, 275, 282, and 303, the APC valve 283, and the vacuum pump 284 can be used as a gas control part configured to be capable of controlling the supply and exhaust of a gas to and from the process chamber 201.

The controller 600 according to the present embodiments can be configured by installing a program in a computer using an external storage device 682 (for example, a magnetic disk such as a hard disk, an optical disk such as a DVD, a magneto-optical disk such as an MO, or a semiconductor memory such as a USB memory) storing the above-described program. The means for supplying the program to the computer is not limited to supplying the program via the external storage device 682. For example, the program may be supplied using communication means such as the Internet or a dedicated line without using the external storage device 682. The storage device 603 and the external storage device 682 are configured as computer-readable recording media in which programs are recorded. Hereinafter, these are collectively referred to simply as “recording media.” In this specification, when the term “recording medium” is used, it may include only the storage device 603, only the external storage device 682, or both.

### (2) Substrate Processing Process

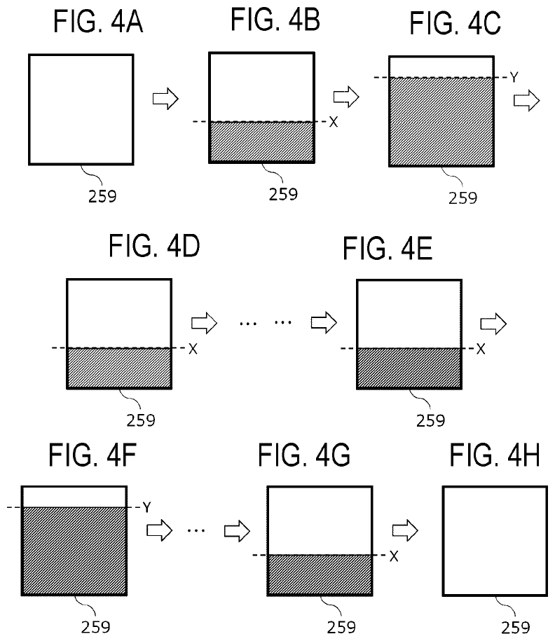

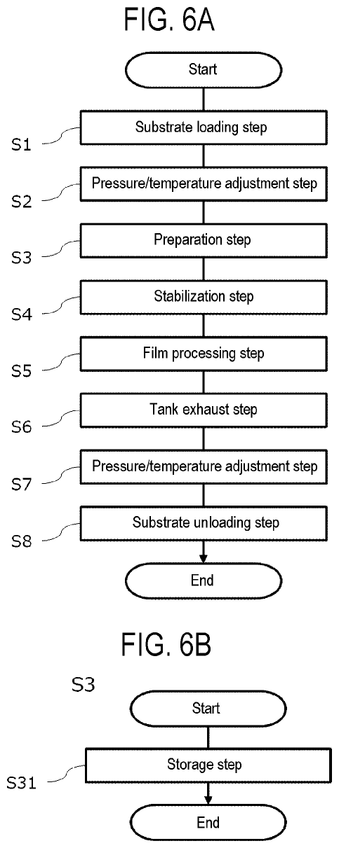

Next, as one of processes of manufacturing a semiconductor device, a substrate processing process of forming a thin film on a substrate S using the substrate processing apparatus 10 having the above-described configuration will be described with reference to FIGS. 4A to 4H and 6A to 6D. Here, recesses such as trenches and holes are formed on the surface of the substrate S. In this substrate processing process, as shown in FIG. 6A, a substrate loading step S1, a pressure/temperature adjustment step S2, a preparation step S3, a stabilization step S4, a film processing step S5, a tank exhaust step S6, a pressure/temperature adjustment step S7, and a substrate unloading step S8 are performed. FIG. 4 illustrates an amount of the first process gas in the tank 259 during the preparation step S3, the stabilization step S4, the film processing step S5, and the tank exhaust step S6, represented by a height from a bottom of the tank 259 of a hatched region shown in the tank 259. In the following description, operations of respective parts of the substrate processing apparatus 10 are controlled by the controller 600.

When the term “substrate” is used in this specification, it may refer to a substrate itself or a substrate and a stacked body of certain layers or films formed on a surface of the substrate. When the phrase “a surface of a substrate” is used in this specification, it may refer to “a surface of a substrate itself” or “a surface of a certain layer formed on a substrate.” When the expression “a certain layer is formed on a surface of a substrate” is used in this specification, it may mean that “a certain layer is formed directly on a surface of a substrate itself” or that “a certain layer is formed on a layer formed on a substrate.” When the term “wafer” is used in this specification, it may be synonymous with the term “substrate.”

### Substrate Loading Step S1

In the transfer chamber 217, a plurality of substrates S are loaded onto the substrate support 300 (wafer charging). Thereafter, the substrate support 300 is raised by the vertical driving mechanism 400, thereby loading the substrates S into the reaction tube 210, that is, into the process chamber 201 (boat loading).

### Pressure/Temperature Adjustment Step S2

The process chamber 201 is exhausted by adjusting the opening degree of the APC valve 283 and operating the vacuum pump 284 so that the interior of the process chamber 201 reaches a desired pressure (pressure adjustment). In addition, the output of the heater 211 is controlled so that the interior of the process chamber 201 or the substrates S reach a desired temperature (temperature adjustment). That is, the pressure/temperature adjustment step S2 is a step of adjusting at least one selected from the group of a temperature and a pressure in the process chamber 201. Further, the substrate support 300 (and the substrates S) and the partition plate support 310 are rotated by the rotation driving mechanism 430. In addition, the tank 259 is heated by the heater 447 so that the tank 259 or the gas in the tank 259 reaches a desired temperature (tank temperature adjustment).

At this time, the temperature of the first process gas supply system 250 is controlled so that the temperature of the gas supplied from the first process gas source 252 into the tank 259 is lower than the temperature of the tank 259 or the gas in the tank 259. This makes it possible to suppress generation of particles due to liquefaction or solidification of a portion of the first process gas in the tank 259. This operation is continuously performed at least until processing of the substrate S is completed.

### Preparation Step S3

Next, as shown in FIG. 6B, the preparation step S3 including a storage step S31 is performed. The preparation step S3 is an example of a first step in the present disclosure.

### Storage Step S31

Here, a case will be described in which the tank 259 is in a vacuum state at the start of the substrate processing process (or the preparation step S3), as shown in FIG. 4A. This makes it possible to suppress generation of particles in the tank 259.

The storage step S31 is a step of storing the first process gas in the tank 259. With the valves 254, 258, 303, 264, and 268 closed, the valve 275 is opened to start storage of the first process gas into the tank 259. Thereafter, the valve 275 is closed after a predetermined time elapses, thereby ending the storage of the first process gas into the tank 259. The storage step S31 is performed, for example, such that a predetermined amount X of the first process gas is present in the tank 259 at the end of the storage step S31, as shown in FIG. 4B. In other words, the storage step S31 is performed such that the predetermined amount X of the first process gas is present in the tank 259 at the start of the film processing step S5.

Hereinafter, the “flow rate of a gas stored in the tank 259 in a given step” may be referred to as a “storage flow rate in that step,” and the “time during which storage of a gas into the tank 259 is continued in a given step” may be referred to as a “storage time in that step.” The amount of a gas stored in the tank 259 in a given step can be controlled, for example, by adjusting the storage flow rate and/or the storage time in that step. Likewise, the amount of a gas present in the tank 259 at the end of a given step can be controlled by adjusting the storage flow rate and/or the storage time in that step.

### Stabilization Step S4

After the preparation step S3 and before the film processing step S5, the stabilization step S4 is performed in which the first process gas in the tank 259 is heated by the heater 447. As a result, a difference in temperature between the first process gas in the tank 259 and the tank 259 itself is reduced, or is made zero (achieving a thermal equilibrium state). The stabilization step S4 is performed, for example, for a time equal to or longer than the time from the end of a supply step S512 to the start of the next storage step S511 in the film processing step S5 to be described later.

Note that at least a portion of the preparation step S3 and at least a portion of the stabilization step S4 may be performed simultaneously with at least one selected from the group of the substrate loading step S1 and the pressure/temperature adjustment step S2. In this case, the time required for the substrate processing process can be shortened.

### Film Processing Step S5

Next, as shown in FIG. 6C, a processing cycle including a first process gas supply step S51, a purge gas supply step S52, a second process gas supply step S53, and a purge gas supply step S54 is performed a predetermined number of times (n times, where n is an integer of 1 or more). The film processing step S5 is an example of a second step in the present disclosure.

### First Process Gas Supply Step S51

In the first process gas supply step S51, as shown in FIG. 6D, “flash supply” is performed in which the first process gas is stored in the tank in the storage step S511 and the first process gas stored in the tank 259 is supplied to the process chamber 201 (or the substrate S) in the supply step S512. The storage step S511 and the supply step S512 may be collectively referred to as a flash supply.

### Storage Step S511

The storage step S511 is a step of storing the first process gas in the tank 259. Storage of the first process gas into the tank 259 is started by the same procedure as in the storage step S31. At this time, as shown in FIG. 4B, the first process gas is supplied into the tank 259 in which the predetermined amount X of the first process gas is already present. Thereafter, the valve 275 is closed after a predetermined time elapses, thereby ending the storage step S511. The storage step S511 is performed such that a predetermined amount Y of the first process gas is present in the tank 259 at the end of the storage step S511, as shown in FIG. 4C.

Here, it is preferable that, at the start of the supply step S512, the tank 259 and the temperature of the first process gas in the tank 259 are in a non-thermal equilibrium state, for reasons to be described later. That is, it is preferable to start the supply step S512 before the temperature of the first process gas in the tank 259 stabilizes.

### Supply Step S512

The supply step S512 is started by opening the valve 254 with the valves 258, 275, 303, 264, and 268 closed. As a result, at least a portion of the first process gas stored in the tank 259 in the state shown in FIG. 4C is supplied to the substrate S accommodated in the process chamber 201. Thereafter, the supply step S512 is ended by closing the valve 254 after a predetermined time elapses. As a result, a first layer composed of at least a portion of the molecular structure of the first process gas is formed on the substrate S. The supply step S512 may be performed under conditions in which the process gas decomposes in the process chamber. In the supply step S512, it is preferable that the valve 282 and the APC valve 283 are in an open state. This allows the flow velocity of the first process gas in the process chamber 201 to be increased, thereby suppressing decomposition of the first process gas.

Hereinafter, the “flow rate of a gas supplied from the tank 259 to the substrate S or the process chamber 201 in a given step” may be referred to as a “supply flow rate in that step,” and the “time during which supply of a gas from the tank 259 to the substrate S or the process chamber 201 is continued in a given step” may be referred to as a “supply time in that step.” The amount of a gas supplied from the tank 259 to the substrate S or the process chamber 201 in a given step can be controlled, for example, by adjusting the supply flow rate and/or the supply time in that step. Likewise, the amount of a gas present in the tank 259 at the end of a given step can be controlled by adjusting the supply flow rate and/or the supply time in that step.

Here, as shown in FIG. 4D, it is preferable that the supply step S512 be performed such that a predetermined amount X of the first process gas remains in the tank 259 at the end of the supply step S512. The predetermined amount X may be set to any value of 0.1% to 99% of the amount (predetermined amount Y) of the first process gas stored in the tank 259 at the start of the supply step S512. In this case, the supply step S512 may be ended when the pressure in the tank 259 measured by the sensor 301 decreases to a predetermined pressure. Further, the amount of the first process gas in the tank 259 at the end of the supply step S512 may be controlled by adjusting the predetermined pressure.

For example, the predetermined amount X remaining in the tank 259 at the end of the supply step S512 may be set such that the decomposition rate of the first process gas in the process chamber 201 is equal to or less than a predetermined decomposition rate. This makes it possible to prevent the film thickness from becoming non-uniform in the recesses formed on the surface of the substrate S, which is caused by generation of highly reactive products due to decomposition of the first process gas. That is, step coverage can be improved.

Further, for example, the predetermined amount X may be set such that the flow velocity of the first process gas in the process chamber 201 during the supply step S512 is equal to or greater than a predetermined flow velocity. This makes it possible to prevent the decomposition rate of the first process gas supplied to the substrate S from becoming higher than a predetermined decomposition rate, thereby improving step coverage. As the flow velocity of the first process gas, an average flow velocity of the first process gas on the substrate S or in the process chamber 201 may be used, or a flow velocity at a certain point on the substrate S or in the process chamber 201 may be used.

Further, for example, the predetermined amount X may be set such that the partial pressure of the first process gas in a space in which the substrate S is present in this step is equal to or greater than a predetermined partial pressure. This allows the first process gas to easily reach a deeper part of the recesses, thereby improving the step coverage.

In the supply step S512, the valve 258 may be opened to supply an inert gas into the gas supply pipe 251 via the gas supply pipe 255. Further, in order to prevent intrusion of the first process gas into the gas supply pipe 261, the valves 268 and 264 may be opened to supply an inert gas into the gas supply pipe 261.

### Purge Gas Supply Step S52

In the purge gas supply step S52, the process chamber 201 is purged. Specifically, with the valves 275, 303, and 264 closed, the valves 254, 258, and 268 are opened to supply an inert gas as a purge gas into the process chamber 201, and the process chamber is exhausted by the vacuum pump 284.

### Second Process Gas Supply Step S53

In the second process gas supply step S53, the valve 264 is opened with the valves 254, 258, 275, 303, and 268 closed, and the valve 264 is closed after a predetermined time elapses. As a result, the second process gas whose flow rate is adjusted by the MFC 263 is supplied to the substrate S in the process chamber 201 and then exhausted. By supplying the second process gas to the substrate S, the first layer on the substrate S can be modified into a second layer. At this time, the valve 282 and the APC valve 283 are in an open state. Here, the valve 268 may be opened to flow an inert gas into the gas supply pipe 261 via the gas supply pipe 265. Further, the valves 258 and 254 may be opened to flow an inert gas into the gas supply pipe 251.

### Purge Gas Supply Step S54

In the purge gas supply step S54, the process chamber 201 is purged by the same procedure as in the purge gas supply step S52 described above.

### Performing Predetermined Number of Times

A processing cycle including the first process gas supply step S51, the purge gas supply step S52, the second process gas supply step S53, and the purge gas supply step S54 is performed a predetermined number of times (n times, where n is an integer of 1 or more). As a result, a film having a predetermined thickness and containing an element derived from the first process gas and an element derived from the second process gas is formed on the substrate S having recesses.

Here, in the storage step S511 of the first process gas supply step S51 in the second and subsequent processing cycles, the first process gas is supplied into the tank 259 in which the predetermined amount X of the first process gas is present, as shown in FIG. 4E. Then, the storage step S511 is performed such that a predetermined amount Y of the first process gas is present in the tank 259 at the end of the storage step S511, as shown in FIG. 4F.

In the first process gas supply step S51 of the second and subsequent processing cycles, at least one selected from the group of the purge gas supply step S52, the second process gas supply step S53, and the purge gas supply step S54 may be partially performed simultaneously with the storage step S511. This makes it possible to improve throughput.

### Tank Exhaust Step S6

After the film processing step S5, a step of exhausting the interior of the tank 259 is performed as the tank exhaust step S6. After completion of the supply step S512 in the n-th processing cycle, the tank exhaust step S6 is started by opening the valve 303 while the valves 254, 258, 275, 264, and 268 are in a closed state. As a result, as shown in FIG. 4G, the first process gas in the tank 259 is exhausted by the vacuum pump 284. For example, after the interior of the tank 259 reaches a vacuum state as shown in FIG. 4H, the tank exhaust step S6 is terminated by closing the valve 303. Thereafter, the vacuum state inside the tank 259 is maintained until the start of the next substrate processing process. This makes it possible to suppress generation of particles caused by partial liquefaction, solidification, or decomposition reactions of the first process gas inside the tank 259. Further, in the tank exhaust step S6, the interior of the tank 259 may be purged. Specifically, while exhausting the interior of the tank 259 by the vacuum pump 284, an inert gas may be supplied to the tank 259 from an inert gas supply source (not shown).

### Pressure/Temperature Adjustment Step S7

An inert gas serving as a purge gas is supplied into the process chamber 201 and exhausted from the exhaust pipe 281. As a result, gases and reaction by-products remaining in the process chamber 201 are removed from the process chamber 201. Thereafter, the internal atmosphere of the process chamber 201 is replaced with the inert gas, and the internal pressure of the process chamber 201 is returned to atmospheric pressure (return to atmospheric pressure). In addition, the output of the heater 211 is controlled so that the process chamber 201 reaches a desired temperature (temperature adjustment).

### Substrate Unloading Step S8

The base flange 401 is lowered by the vertical driving mechanism 400, thereby opening the lower end of the reaction tube 210. Then, while being supported by the substrate support 300, the processed substrate S is unloaded to the transfer chamber 217 (boat unloading). The processed substrate S is taken out from the substrate support 300 in the transfer chamber 217 (wafer discharging).

The tank exhaust step S6 may be performed while either the pressure/temperature adjustment step S7 or the substrate unloading step S8 is being performed. In this case, the time required for the substrate processing process can be shortened.

According to the present embodiment, in addition to the above-described effects, one or more of the following effects can be obtained.

(a) Some of the effects obtained by the present embodiments will be described based on a comparison between the present embodiments and a comparative example. In the comparative example, substrate processing is performed using the above-described substrate processing apparatus 10 without performing the above-described preparation step S3 and stabilization step S4. Other steps are performed in the same manner as in the present embodiment, and elements that are substantially the same as those described in the present embodiments are denoted by the same reference numerals, and description thereof may be omitted.

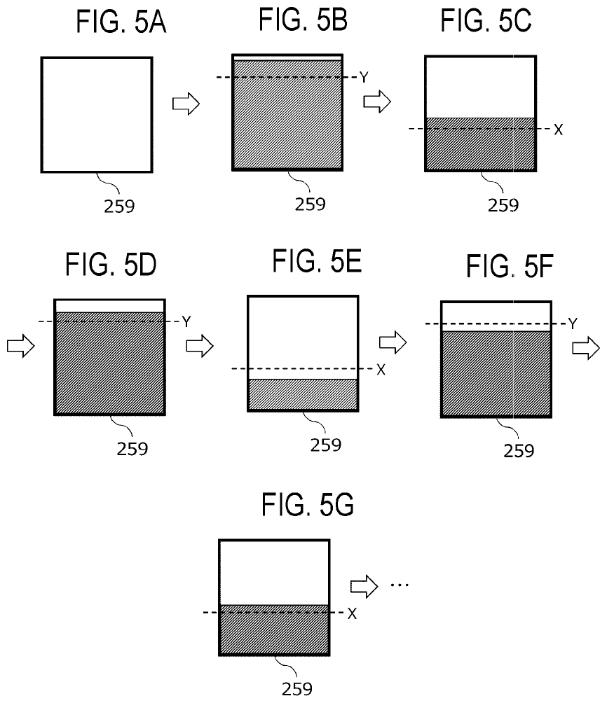

FIGS. 5A to 5G illustrates the amount of the first process gas inside the tank 259 in the first to third processing cycles of the comparative example. In the comparative example, at the start of the storage step S511 in the first processing cycle, the interior of the tank 259 is vacuum-exhausted, as shown in FIG. 5A. In contrast, at the start of the storage step S511 in the second and subsequent processing cycles, a predetermined amount X, or an amount slightly different from the predetermined amount X, of the first process gas is present inside the tank 259, as shown in FIG. 5C. Due to such a difference in the gas amount, a difference occurs in the amount of heat received by the first process gas stored in the tank 259 during the storage steps S511 of the first and second cycles. As a result, as shown in FIGS. 5B and 5D, variations occur in the state inside the tank 259 at the start of the supply step S512 in the first and second cycles, thereby causing variations in the processing results on the substrate S. Here, the “state inside the tank 259” refers to at least one selected from the group of the amount, temperature, and pressure of the first process gas present in the tank 259, or the temperature of the tank 259 itself.

Further, when a difference in the state inside the tank 259 between the first and second processing cycles is large, variations in the state inside the tank 259 and variations in processing results, as shown in FIGS. 5C to 5G, may continuously occur even in the second and subsequent processing cycles. Such variations decrease each time the processing cycle is repeated, and, for example, continue to occur from the first to the twentieth processing cycles. In other words, variations in the processing performed on the substrate S are likely to occur between processing cycles performed in the early stage and those performed thereafter.

In the present embodiment, by performing the preparation step S3, as shown in FIGS. 4B and 4D, a difference in the amount of gas inside the tank 259 at the start of the storage step S511 in the first and second cycles can be reduced or made zero. Therefore, variations in the processing performed on the substrate S between processing cycles performed in the early stage and those performed thereafter can be reduced.

(b) In the present embodiment, the stabilization step S4 is performed after the preparation step S3. This makes it possible to further reduce the difference in the state inside the tank 259 before the start of the storage step S511 between the first processing cycle and the second and subsequent processing cycles.

(c) In the present embodiment, the stabilization step S4 is performed for the same duration as the time from the end of the supply step S512 in the film processing step S5 to the start of the next storage step S511. This makes it possible to further reduce the difference in the state inside the tank 259 before the start of the storage step S511 between the first processing cycle and the second and subsequent processing cycles.

(d) In the present embodiment, a predetermined amount X of the first process gas is present inside the tank 259 at the end of the supply step S512. In such a case, a difference in the state inside the tank 259 before the start of the storage step S511 between the first processing cycle and the second and subsequent processing cycles tends to increase. In the present embodiment, this influence can be reduced by performing the preparation step S3 such that the predetermined amount X of the first process gas is present inside the tank 259, as shown in FIG. 4B.

(e) In the present embodiment, the first process gas is a gas obtained by vaporizing a liquid or solid, and the temperature of the gas supplied from the first process gas source 252 into the tank 259 is set to be lower than the temperature of the tank 259 or the gas inside the tank 259. Even in such a case, by using the technique of the present disclosure, the difference in the state inside the tank 259 at the start of the storage step S511 between processing cycles can be reduced.

(f) When the supply step S512 is performed under conditions such that decomposition occurs in the process chamber 201 (or on the surface of the substrate S), variations in the processing results caused by variations in the state of the first process gas supplied to the substrate S between processing cycles become larger. Even in such a case, by using the technique of the present disclosure, variations in the state of the first process gas supplied to the substrate S between processing cycles can be reduced.

(g) In the present embodiment, the interior of the tank 259 is set to a vacuum state at the start of the substrate processing process, that is, at the start of the storage step S31. In such a case, the difference in the state inside the tank 259 before the start of the storage step S511 between the first processing cycle and the second and subsequent processing cycles tends to increase. Even in such a case, by using the technique of the present disclosure, variations in the state of the first process gas supplied to the substrate S between processing cycles can be reduced.

### (3) Modifications

Hereinafter, Modification 1 and Modification 2, which are modifications of the above-described embodiment, will be described. In the descriptions of Modification 1 and Modification 2, the following substrate processing process is performed using the above-described substrate processing apparatus 10. The following description focuses mainly on steps different from those of the above-described substrate processing process. Steps common to the above-described substrate processing process are performed in the same manner, and substantially same elements are denoted by the same reference numerals, and description thereof may be omitted. According to Modification 1 and Modification 2, one or more of the following effects can be obtained in addition to the above-described effects.

### Modification 1

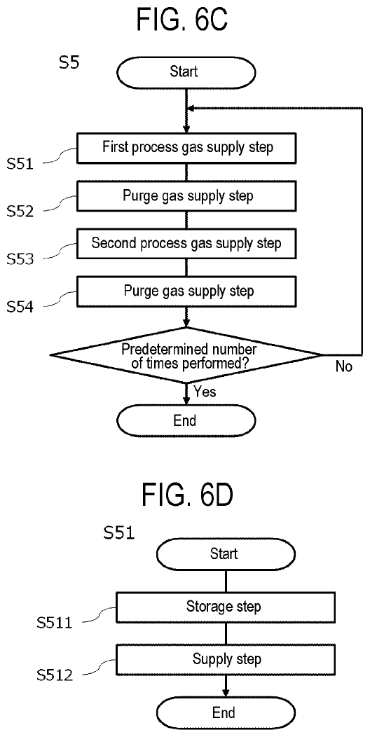

In Modification 1, instead of the preparation step S3 in the above-described embodiment, a preparation step S3′ as shown in FIG. 7 is performed. The preparation step S3′ is an example of the first step in the present disclosure. In Modification 1, for example, the substrate processing process is performed in the order of the substrate loading step S1, the pressure/temperature adjustment step S2, the preparation step S3′, the stabilization step S4, the film processing step S5, the tank exhaust step S6, the pressure/temperature adjustment step S7, and the substrate unloading step S8.

### Preparation Step S3′

### Storage Step S31′

In the storage step S31′, the first process gas is stored in the tank 259 by the same procedure as in the storage step S31. The storage step S31′ is performed, for example, such that the amount of the first process gas in the tank 259 at the end of the storage step S31′ becomes approximately the same as that at the end of the storage step S511 in the processing cycle.

### Discharge Step S32′

The discharge step S32′ is a step of discharging at least a portion of the first process gas in the tank 259 from the tank 259 so that the first process gas is not supplied to the substrate S. In the discharge step S32′, at least a portion of the first process gas stored in the tank 259 is exhausted by the vacuum pump 284 by the same procedure as in the tank exhaust step S6. The discharge step S32′ is performed, for example, such that the amount of the first process gas in the tank 259 at the end of the discharge step S32′ becomes approximately the same as that at the end of the supply step S512 in the processing cycle.

The amount of gas discharged from the tank 259 in the discharge step S32′ and the amount of gas remaining in the tank 259 at the end of the discharge step S32′ are controlled, for example, by the exhaust time of the tank 259. At this time, the supply step S512 may be ended when the internal pressure of the tank 259 measured by the sensor 301 decreases to a predetermined pressure. Alternatively, by adjusting the predetermined pressure, the amount of the first process gas in the tank 259 at the end of the supply step S512 may be controlled.

By performing the preparation step S3′ further including the discharge step S32′ in this manner, it is possible to start the first processing cycle after the storage and discharge of the first process gas have been performed in the tank 259, as in the second and subsequent processing cycles. Therefore, variations in the state of the tank 259 at the start of the storage step S511 between the first and second processing cycles can be further reduced.

In the discharge step S32′, the first process gas discharged from the tank 259 is discharged through a path that does not pass through the process chamber 201. As a result, the preparation step S3′ can be performed in parallel with other steps such as the substrate loading step S1 and the pressure/temperature adjustment step S2, thereby improving throughput.

### Performing Predetermined Number of Times

A preparation cycle including the above-described storage step S31′ and discharge step S32′ is performed a predetermined number of times (m times, where m is an integer of 1 or more). The preparation cycle is performed, for example, 1 to 20 times. As described above, variations in the processing performed on the substrate S are likely to occur between processing cycles performed in the early stage and those performed thereafter. Therefore, by performing the preparation cycle a plural number of times in the preparation step S3′, a difference in the state of the tank 259 before the start of the storage step S511 between the first processing cycle and the second and subsequent processing cycles can be further reduced.

### Modification 2

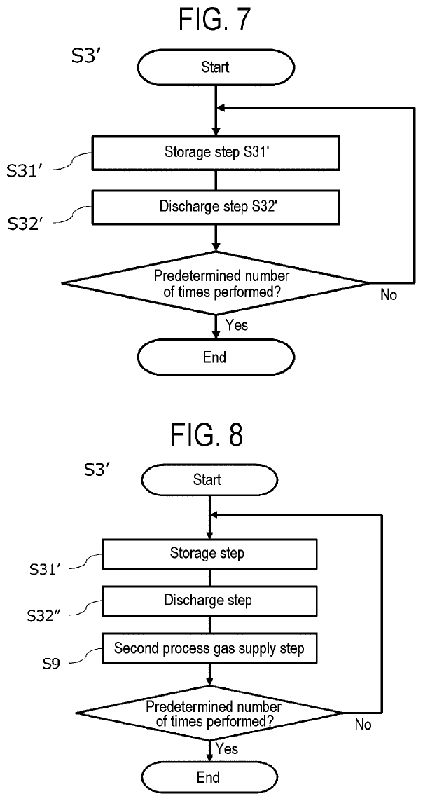

In Modification 2, in the preparation step S3′ described in Modification 1, a discharge step S32″ and a second process gas supply step S9 as shown in FIG. 8 are performed instead of the discharge step S32′. In Modification 2, the preparation step S3′ is started before the substrate loading step S1. That is, Modification 2 is performed, for example, in the order of the preparation step S3′, the substrate loading step S1, the pressure/temperature adjustment step S2, the stabilization step S4, the film processing step S5, the tank exhaust step S6, the pressure/temperature adjustment step S7, and the substrate unloading step S8. Further, in Modification 2, the second process gas supply step S9 may be omitted.

### Discharge Step S32″

The discharge step S32″ is a step of discharging at least a portion of the first process gas in the tank 259 from the tank 259 so that the first process gas is not supplied to the substrate S. The discharge step S32″ is started and ended by the same procedure as the supply step S512. At this time, the valve 282 and the APC valve 283 are opened so that the gas in the process chamber 201 is exhausted by the vacuum pump 284. That is, in the discharge step S32″, the first process gas discharged from the tank 259 is exhausted through a path passing through the process chamber 201. At this time, a first layer containing at least a portion of the molecular structure of the first process gas may be formed on at least a portion of the surface of the process chamber 201. The discharge step S32″ is performed, for example, such that the amount of the first process gas in the tank 259 at the end of the discharge step S32″ becomes approximately the same as that at the end of the supply step S512 in the processing cycle.

In the discharge step S32″, the discharge step S32′ can be performed with the gas conductance in a gas path from the tank 259 to the vacuum pump 284 being approximately the same as that in the supply step S512. Therefore, a difference in the state of the tank 259 before the start of the storage step S511 between the first processing cycle and the second and subsequent processing cycles can be further reduced.

### Second Process Gas Supply Step S9

In the second process gas supply step S9, the second process gas is supplied into the process chamber 201 in which no substrate S is present. The second process gas supply step S9 can be started and ended by the same procedure as the second process gas supply step S53. At this time, the second process gas supply step S9 may modify the first layer formed on the surface of the process chamber 201 in the discharge step S32″ into a second layer.

By performing the discharge step S32″ and the second process gas supply step S9, a film similar to that formed on the substrate S in the film processing step S5 can be formed, that is, pre-coated, on the inner wall surface of the process chamber 201. By pre-coating the inner wall surface of the process chamber 201, for example, it is possible to suppress a decrease in the amount of processing gas supplied to the substrate S due to reactions of the process gas (the first process gas and/or the second process gas) on the surfaces of members inside the process chamber 201 during the film processing step S5. In addition, since the preparation step S3′ and the pre-coating of the inner wall surface of the process chamber 201 can be performed simultaneously, consumption of the first process gas can be reduced.

In the preparation step S3′ of Modification 2, both the discharge step S32″ and the discharge step S32′ may be performed. For example, in the preparation step S3′, the discharge step S32″ may be performed one or more times, and then the discharge step S32′ may be performed one or more times. Even in this case, the same effects as those described above are obtained.

### Other Embodiments

Although embodiments of the present aspect have been described above in detail, the present disclosure is not limited thereto, and various modifications may be made without departing from the gist thereof.

In the present embodiments, a case has been described in which the first process gas is not stored in the tank 259 in the stabilization step S4. However, the technique of the present disclosure is not limited thereto. As the stabilization step S4, the first process gas may be stored in the tank 259 at a flow rate smaller than that in the preparation step S3. Alternatively, as the stabilization step S4, the first process gas may be stored in the tank 259 at a flow rate smaller than those in the preparation step S3 and the storage step S511. Even in these cases, some of the effects of the stabilization step S4 can be obtained, and the time required for the substrate processing process can be shortened.

It is preferable that the tank 259 and the first process gas in the tank 259 are in a non-thermal equilibrium state during the period from the end of the storage step S511 to the start of the supply step S512. In this case, it is not necessary to provide a time for bringing the tank 259 and the first process gas in the tank 259 into a thermal equilibrium state (a state in which the temperature difference between the two is stabilized at zero) after the end of the storage step S511 of each cycle. On the other hand, if there is a difference in the state of the tank 259 at the start of the storage step S511 between two cycles, variations are likely to occur in the state of the first process gas supplied from the tank 259 in the supply step S512. However, by using the technique of the present disclosure, this influence can be reduced. Accordingly, it is possible to improve throughput while suppressing variations in the processing performed on the substrate S between processing cycles.

In the above-described embodiments and Modifications 1 and 2, an example has been described in which the first process gas (raw material gas) is flash-supplied to the substrate S and then the second process gas (reaction gas) is supplied to the substrate S. However, the present disclosure is not limited thereto. For example, the first process gas may be supplied to the substrate S and then the second process gas may be flash-supplied to the substrate S, or both the first process gas and the second process gas may be supplied to the substrate S. Even in these cases, the above-described effects can be obtained.

As the raw material gas, for example, a predetermined element-containing gas containing a predetermined element such as tungsten (W), titanium (Ti), molybdenum (Mo), tantalum (Ta), cobalt (Co), yttrium (Y), ruthenium (Ru), hafnium (Hf), zirconium (Zr), aluminum (Al), silicon (Si), or the like can be used. One or more of these gases may be used as the raw material gas. As the raw material gas, a gas obtained by activating these gases by plasma or the like may also be used.

As the predetermined element-containing gas, for example, a halogen-based predetermined element-containing gas containing a predetermined element and a halogen element can be used. Examples of the halogen-based predetermined element-containing gas may include hexachlorotungsten (WCl₆), hexafluorotungsten (WF₆), titanium tetrachloride (TiCl₄), titanium tetrafluoride (TiF₄), molybdenum pentachloride (MoCl₅), molybdenum pentafluoride (MoF₅), molybdenum dioxide dichloride (MoO₂Cl₂), molybdenum oxide tetrachloride (MoOCl₄), tantalum pentachloride (TaCl₅), tantalum pentafluoride (TaF5), cobalt difluoride (CoF₂), cobalt dichloride (CoCl₂), yttrium trifluoride (YF₃), yttrium trichloride (YCl₃), ruthenium trichloride (RuCl₃), ruthenium trifluoride (RuF₃), hafnium tetrachloride (HfCl₄), hafnium tetrafluoride (HfF₄), zirconium tetrachloride (ZrCl₄), zirconium tetrafluoride (ZrF₄), aluminum trichloride (AlCl₃), aluminum trifluoride (AlF₃), dichlorosilane (SiH₂Cl₂), 1,2-dichlorodisilane (Si₂H₄Cl₂), 1,1,1-trichlorodisilane (Si₂H₃Cl₃), 1,1,2-trichlorodisilane (Si₂H₃Cl₃), pentachlorodisilane (Si₂HCl₅), hexachlorodisilane (Si₂Cl₆), tetrafluorosilane (SiF₄), and the like. Further, as the predetermined element-containing gas, for example, a gas containing monosilane (SiH₄), disilane (Si₂H₆), trisilane (Si₃H₈), tetrasilane (Si₄H₁₀), or the like can be used. One or more of these gases may be used as the predetermined element-containing gas.

Furthermore, as the predetermined element-containing gas, for example, an organic predetermined element-containing gas having a predetermined element and an organic ligand can be used. Examples of the organic predetermined element-containing gas may include hexadimethylaminoditungsten (W₂[N(CH₃)₂]₆), bis(tertiarybutylimido)bis(dimethylamido)tungsten ((t-C₄H₉NH)₂W=(Nt-C₄H₉)₂), tetrakisethylmethylaminotitanium (Ti[N(C₂H₅)(CH₃)]₄), bisethylcyclopentadienylruthenium (Ru(EtCp)₂), biscyclopentadienylruthenium (Ru(Cp)₂), tetrakisethylmethylaminohafnium (Hf[N(Me)Et]₄), tetrakisdiethylaminohafnium (Hf[N(Et)₂]₄), tetrakisdimethylaminohafnium (Hf[N(Me)₂]₄), trisdimethylaminocyclopentadienylhafnium ((Cp)Hf[N(Me)₂]₃), tetrakisethylmethylaminozirconium (Zr[N(Me)Cp]₄), tetrakisdiethylaminozirconium (Zr[N(Et)₂]₄), tetrakisdimethylaminozirconium (Zr[N(Me)₂]₄), trisdimethylaminocyclopentadienylzirconium ((Cp)Zr[N(Me)₂]₃), trimethylaluminum (Al(CH₃)₃), trisdimethylaminosilane (Si[N(CH₃)₂]₃H), and the like. One or more of these gases can be used as the predetermined element-containing gas.

As the reaction gas, for example, a gas containing a reducing gas, an oxidizing gas, a nitriding gas, a sulfurizing gas, a selenizing gas, or a tellurizing gas can be used. One or more of these gases can be used as the reaction gas. As the reaction gas, a gas obtained by activating these gases by plasma or the like may also be used. For example, when the first process gas is a predetermined element-containing gas and the second process gas is a reducing gas, a film composed of a single predetermined element can be formed on the substrate S. Further, for example, when the first process gas is a predetermined element-containing gas and the second process gas is any one of an oxidizing gas, a nitriding gas, a sulfurizing gas, a selenizing gas, and a tellurizing gas, an oxide film of the predetermined element, a nitride film of the predetermined element, a sulfide film of the predetermined element, a selenide film of the predetermined element, and a telluride film of the predetermined element can be formed on the substrate S.

Examples of the reducing gas may include one or more of hydrogen (H₂) gas, deuterium (D₂) gas, borane (BH₃) gas, diborane (B₂H₆) gas, carbon monoxide (CO) gas, ammonia (NH₃) gas, monosilane (SiH₄) gas, disilane (Si₂H₆) gas, trisilane (Si₃H₈) gas, monogermane (GeH₄) gas, digermane (Ge₂H₆) gas, and the like. Examples of the reaction gas may include an oxidizing gas that is an oxygen (O)-containing gas. Examples of the oxidizing gas may include one or more of oxygen (O₂) gas, ozone (O₃) gas, water vapor (H₂O), a mixed gas of H₂ and O₂, hydrogen peroxide (H₂O₂) gas, nitrous oxide (N₂O) gas, and the like. Examples of the nitriding gas may include one or more of hydrogen nitride-based gases such as ammonia (NH₃) gas, diazene (N₂H₂) gas, hydrazine (N₂H₄) gas, and N₃H₈ gas. Examples of the sulfurizing gas may include a gas containing sulfane (H₂S), disulfane (H₂S₂), diammonium sulfide ((NH₄)₂S), dimethyl sulfide ((CH₃)₂S), or the like. One or more of these gases can be used as the sulfurizing gas. Examples of the selenizing gas may include a gas containing selerane (H₂Se), diselerane (H₂Se₂), dimethylselenium ((CH₃)₂Se), or the like. One or more of these gases can be used as the selenizing gas. Examples of the tellurizing gas may include a gas containing tellurane (H₂Te), ditellurane (H₂Te₂), dimethyltellurium ((CH₃)₂Te), or the like. One or more of these gases can be used as the tellurizing gas.

Examples of the inert gas may include rare gases such as helium (He) gas, argon (Ar) gas, neon (Ne) gas, xenon (Xe) gas, nitrogen (N₂), and the like. One or more of these gases may be used as the inert gas.

In the above-described embodiments, an example has been described in which a film is formed on the substrate S using the first process gas and the second process gas. However, the present disclosure is not limited thereto. For example, the technique of the present disclosure can be applied even when three or more types of processing gases are used.

In the above-described embodiments, an example has been described in which a film is formed using a batch-type substrate processing apparatus that processes a plurality of substrates at a time. However, the present disclosure is not limited thereto. For example, the present disclosure can also be suitably applied to a case where a film is formed using a single-wafer type substrate processing apparatus that processes one or several substrates at a time. Further, in the above-described embodiments, an example has been described in which a film is formed using a substrate processing apparatus having a hot-wall type processing furnace. However, the present disclosure is not limited thereto. The present disclosure can also be suitably applied to a case where a film is formed using a cold-wall type processing furnace having a cold-wall type processing furnace, and the same effects as those of the above-described embodiments and modifications can be obtained.

The above-described embodiments and Modifications 1 and 2 can be used in proper combination. In this case, the processing procedure and processing conditions may be the same as those of, for example, the above-described embodiments and Modification 1 and 2.

According to the present disclosure, it is possible to suppress variations in substrate processing.

While certain embodiments are described, these embodiments are presented by way of example, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate, comprising:
a first step including:
(a1) storing a process gas in a reservoir; and
a second step of performing a cycle a predetermined number of times after the first step, the cycle including sequentially performing:
(b1) storing the process gas in the reservoir; and
(b2) supplying at least a portion of the process gas in the reservoir to the substrate accommodated in a process chamber.

2. The method of claim 1, wherein the process gas is a gas obtained by vaporizing a liquid or a solid.

3. The method of claim 2, wherein a temperature of the process gas before being stored in the reservoir is set to be lower than a temperature of the reservoir.

4. The method of claim 1, further comprising after the first step and before the second step:
(c) reducing a difference between a temperature of the process gas in the reservoir and a temperature of the reservoir.

5. The method of claim 4, wherein, in (c), the process gas is not stored in the reservoir, or, in (c), the process gas is stored in the reservoir at a flow rate lower than a storage flow rate in (a1).

6. The method of claim 4, wherein (c) is performed for a time equal to or longer than a time from an end of (b2) to a start of the next (b1).

7. The method of claim 1, wherein (b2) is performed under a condition in which the process gas decomposes in the process chamber.

8. The method of claim 1, wherein (b2) is performed such that a predetermined amount of the process gas is present in the reservoir at an end of (b2).

9. The method of claim 8, wherein the first step is performed such that the predetermined amount of the process gas is present in the reservoir at a start of the second step.

10. The method of claim 1, further comprising after the second step:
(d) exhausting an inside of the reservoir.

11. The method of claim 1, wherein an inside of the reservoir is in a vacuum state at a start of the first step.

12. The method of claim 1, wherein, at a start of (b2), the reservoir and the process gas in the reservoir are in a non-thermal equilibrium state.

13. The method of claim 1, further comprising:
(e) loading the substrate into the process chamber; and
(f) adjusting at least one selected from the group of a temperature and a pressure in the process chamber,
wherein at least a portion of the first step is performed simultaneously with at least one selected from the group of (e) and (f).

14. The method of claim 1, wherein the first step further includes:
(a2) discharging at least a portion of the process gas in the reservoir from the reservoir so that the process gas is not supplied to the substrate.

15. The method of claim 14, wherein, in the first step, a cycle including (a1) and (a2) is performed a plurality of times.

16. The method of claim 14, wherein, in (a2), a gas discharged from the reservoir is exhausted through a path that does not pass through the process chamber.

17. The method of claim 14, wherein, in (a2), the process gas discharged from the reservoir is exhausted through a path that passes through the process chamber.

18. A method of manufacturing a semiconductor device comprising the method of claim 1.

19. A substrate processing apparatus comprising:
a process chamber in which a substrate is accommodated;
a process gas supply system including a reservoir in which a process gas is stored, the process gas supply system configured to store the process gas in the reservoir and supply the process gas stored in the reservoir to the substrate; and
a controller configured to be capable of controlling the process gas supply system to perform:
a first process including:
(a1) storing the process gas in the reservoir; and
a second process of performing a cycle a predetermined number of times after the first process, the cycle including sequentially performing:
(b1) storing the process gas in the reservoir; and
(b2) supplying at least a portion of the process gas in the reservoir to the substrate.

20. A non-transitory computer-readable recording medium storing a program that causes, by a computer, a substrate processing apparatus to perform a process comprising:
a first step including:
(a1) storing a process gas in a reservoir; and
a second step of performing a cycle a predetermined number of times after the first step, the cycle including sequentially performing:
(b1) storing the process gas in the reservoir; and
(b2) supplying at least a portion of the process gas in the reservoir to a substrate accommodated in a process chamber.
